(19) United States
(12) Patent Application Publication
(10) Pub. No.: US 2023/0102718 A1
(43) Pub. Date: Mar. 30, 2023

(54) METHOD OF STRIPPING PHOTORESIST

(71) Applicant: CHIPBOND TECHNOLOGY CORPORATION, Hsinchu (TW)

(72) Inventor: Hsueh-Shun Yeh, Hsinchu County (TW)

(21) Appl. No.: 17/860,224

(22) Filed: Jul. 8, 2022

(30) Foreign Application Priority Data
Sep. 24, 2021 (TW) 110135660

(51) Int. Cl. G03F 7/42; G03F 7/11

(52) U.S. Cl. CPC G03F 7/422; G03F 7/11; G03F 7/039

(57) ABSTRACT

A method of stripping photoresist includes the steps of pattering a photoresist located on a substrate to generate an opening showing the substrate, forming a film including a first portion located on a top surface of the photoresist and a second portion located on a surface of the substrate, attaching a tape on the first portion, removing the tape and the first portion to show the top surface of the photoresist, and contacting the top surface and a lateral surface of the photoresist with a photoresist stripping solution to strip the photoresist. The photoresist can be removed completely by increasing its contacting area with the photoresist stripping solution.

### FIELD OF THE INVENTION

This invention relates to a method of stripping photoresist, and more particularly to a method of stripping photoresist with reduced time spent in stripping photoresist by a photoresist stripping solution.

### BACKGROUND OF THE INVENTION

In conventional lift-off patterning, the photoresist is patterned using lithography according to a film deposition site, a film is deposited by sputtering or evaporation, and then the photoresist is removed to show the pattern. Etching process is not required in lift-off patterning so lift-off patterning is simplified in manufacture and can be used to pattern a film incapable of being etched, such as filter film or other optical films. However, sputtering or evaporation deposition is required to be performed in high temperature, it is difficult to remove the heated photoresist completely, and the photoresist residue may disturb the subsequent manufacturing processes. In order to remove the photoresist completely, increasing the time for contacting the photoresist with the photoresist stripper is necessary.

### SUMMARY

One object of the present invention is to provide a method of stripping photoresist, a film attached on a photoresist is removed using a tape before contacting the photoresist with a photoresist stripping solution such that the photoresist stripping solution can contact top and sidewall of the photoresist to strip the photoresist completely with reduced time.

A method of stripping photoresist disclosed in the present invention includes the steps of: forming a photoresist on a surface of a substrate; patterning the photoresist to generate an opening which shows the surface of the substrate; forming a film including a first portion and a second portion, the first portion is located on a top surface of the photoresist, the second portion is located on the surface of the substrate and visible through the opening; attaching a tape on the first portion, a binding force between the first portion and the tape is greater than a binding force between the first portion and the photoresist; removing the tape and the first portion to show the top surface of the photoresist; and contacting the top surface and a lateral surface of the photoresist with a photoresist stripping solution to strip the photoresist.

### DESCRIPTION OF THE DRAWINGS

FIGS. 1 to 6 are cross-section view diagrams illustrating a method of stripping photoresist in accordance with one embodiment of the present invention.

### DETAILED DESCRIPTION OF THE INVENTION

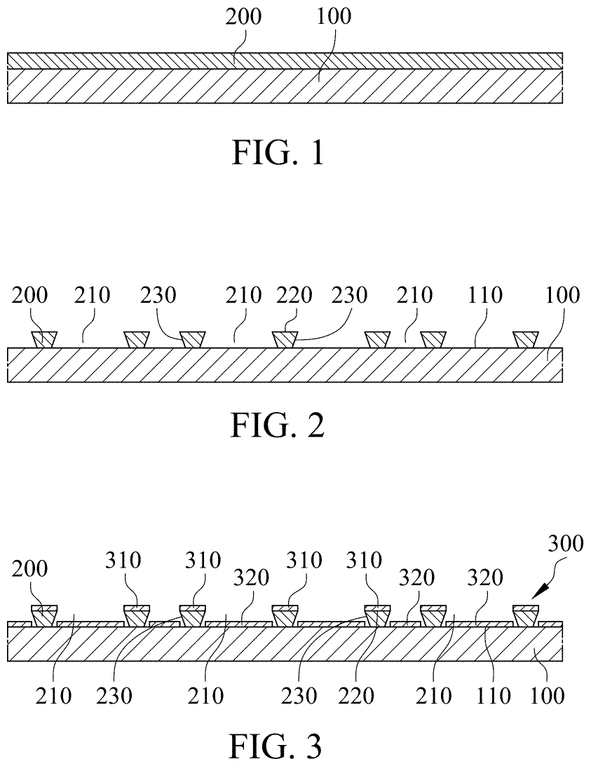

With reference to FIG. 1, in a method of stripping photoresist, firstly, a photoresist 200 is formed on a surface 110 of a substrate 100. The substrate 100 may be made of glass, ceramic, sapphire, monocrystalline silicon, polycrystalline silicon, amorphous silicon or polymer, and the photoresist 200 is positive or negative photoresist.

Referring to FIG. 2, after forming the photoresist 200 on the substrate 100, the photoresist 200 is patterned using lithography to generate at least one opening 210 which shows the surface 110 of the substrate 100. Preferably, the opening 210 has a trapezoidal cross-section, in other words, the opening 210 has a narrow top and a wide bottom in cross-section view, so the width of the opening 210 is increased from a top surface 220 of the photoresist 200 to the surface 110 of the substrate 100.

With reference to FIG. 3, after patterning the photoresist 200, a film 300 is formed on the substrate 100 and the photoresist 200. The film 300 includes a first portion 310 and a second portion 320, the first portion 310 is located on the top surface 220 of the photoresist 200, and the second portion 320 is located on the surface 110 of the substrate 100 and is visible through the opening 210. Preferably, the film 300 is formed on the substrate 100 and the photoresist 200 by sputtering deposition or evaporation deposition. Owing to the opening 210 has a trapezoidal cross-section (narrow top and wide bottom), the deposition of the second portion 320 of the film 300 is limited by the top width of the opening 210. Consequently, the second portion 320 deposited on the substrate 100 does not contact the photoresist 200.

In one embodiment of the present invention, the film 300 is a single metal film or metal alloy film. Preferably, the film 300 is made of gold (Au), silver (Ag), titanium (Ti), nickel (Ni), tungsten-titanium (TiW) alloy or gold-tin (AuSn) alloy. In another embodiment of the present invention, the film 300 is an optical film (e.g. filter film) without metal, preferably, the optical film is made of silicon oxide (SiO_{X}) or silicon nitride (SiN_{X}).

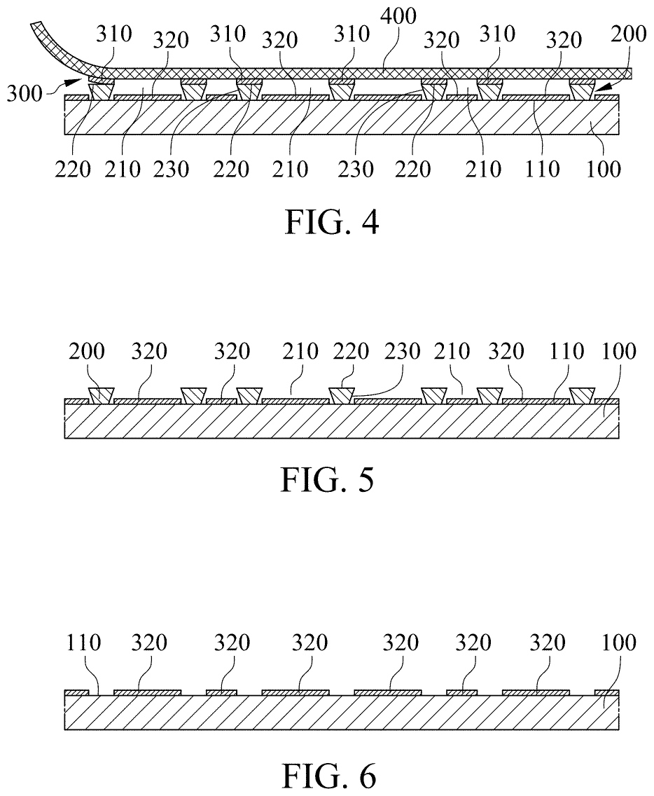

Referring to FIG. 4, after forming the film 300 on the substrate 100 and the photoresist 200, a tape 400 is attached onto the first portion 310 of the film 300. The tape 400 may be a conventional tape used in wafer dicing or used for IC protection, or other conventional tape. With reference to FIG. 5, as the tape 400 is removed, the first portion 310 of the film 300 is also removed together with the tape 400 because the binding force between the first portion 310 and the tape 400 is greater than the binding force between the first portion 310 and the photoresist 200. Consequently, the top surface 220 of the photoresist 200 is shown after removing the tape 400 and the first portion 310 of the film 300.

With reference to FIG. 6, after removing the tape 400 and the first portion 310 of the film 300, the substrate 100 is soaked in a photoresist stripping solution to allow the top surface 220 and a lateral surface 230 of the photoresist 200 to be contacted with the photoresist stripping solution so that the photoresist 200 can be stripped from the substrate 100. Besides, due to the second portion 320 of the film 300 located in the opening 210 is not connected to the photoresist 200, the second portion 320 of the film 300 will not be pulled by the photoresist 200 to be separated from the substrate 100 when the photoresist 200 is stripped from the substrate 100.

The photoresist stripping solution may be a solution including tetramethyl ammonium hydroxide (TMAH) or dimethyl sulfoxide (DMSO), or may be an organic solvent, such as acetone, N-methyl-pyrrolidinone (NMP) or isopropanol (IPA).

In the present invention, before the photoresist 200 is contacted with the photoresist stripping solution, the first portion 310 of the film 300 located on the photoresist 200 is removed by the tape 400 to allow the top surface 220 of the photoresist 200 to be visible. Accordingly, both of the top surface 220 and the lateral surface 230 of the photoresist 200 can be contacted with the photoresist stripping solution to increase contacting area of the photoresist 200 with the photoresist stripping solution. The method of the present invention can significantly reduce contact time of the photoresist 200 in the photoresist stripping solution. Furthermore, if the film 300 is a metal film, metal recovery can be achieved because the first portion 310 of the film 300 is removed by the tape 400 in advance.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

What is claimed is:

1. A method of stripping photoresist comprising the steps of:
forming a photoresist on a surface of a substrate;
patterning the photoresist to generate an opening, the opening is configured to show the surface of the substrate;
forming a film including a first portion and a second portion, the first portion is located on a top surface of the photoresist, the second portion is located on the surface of the substrate and visible through the opening;
attaching a tape on the first portion of the film, a binding force between the first portion of the film and the tape is greater than a binding force between the first portion of the film and the photoresist;
removing the tape and the first portion of the film to show the top surface of the photoresist; and
contacting the top surface and a lateral surface of the photoresist with a photoresist stripping solution, the photoresist stripping solution is configured to strip the photoresist.

2. The method of stripping photoresist in accordance with claim 1, wherein the film is a metal film.

3. The method of stripping photoresist in accordance with claim 2, wherein the metal film is made of gold, silver, titanium, nickel, tungsten-titanium alloy or gold-tin alloy.

4. The method of stripping photoresist in accordance with claim 1, wherein the film is an optical film.

5. The method of stripping photoresist in accordance with claim 4, wherein the optical film is made of silicon oxide or silicon nitride.

6. The method of stripping photoresist in accordance with claim 1, wherein the film is formed by sputtering deposition or evaporation deposition.

7. The method of stripping photoresist in accordance with claim 2, wherein the film is formed by sputtering deposition or evaporation deposition.

8. The method of stripping photoresist in accordance with claim 3, wherein the film is formed by sputtering deposition or evaporation deposition.

9. The method of stripping photoresist in accordance with claim 4, wherein the film is formed by sputtering deposition or evaporation deposition.

10. The method of stripping photoresist in accordance with claim 5, wherein the film is formed by sputtering deposition or evaporation deposition.

11. The method of stripping photoresist in accordance with claim 1, wherein the photoresist is a positive photoresist.

12. The method of stripping photoresist in accordance with claim 1, wherein the photoresist is a negative photoresist.

13. The method of stripping photoresist in accordance with claim 1, wherein the opening has a narrow top and a wide bottom in cross-section.

14. The method of stripping photoresist in accordance with claim 13, wherein the second portion of the film is configured to not contact the photoresist.
